(19) United States
(12) Patent Application Publication
(10) Pub. No.: US 2022/0238336 A1
(43) Pub. Date: Jul. 28, 2022

(54) FACET SUPPRESSION OF GALLIUM ARSENIDE SPALLING USING NANOIMPRINT LITHOGRAPHY AND METHODS THEREOF

(71) Applicants: Alliance for Sustainable Energy, LLC, Golden, CO (US); Colorado School of Mines, Golden, CO (US)

(72) Inventors: Aaron Joseph PTAK, Littleton, CO (US); Corinne Evelyn PACKARD, Lakewood, CO (US)

(21) Appl. No.: 17/585,096

(22) Filed: Jan. 26, 2022

Related U.S. Application Data
(60) Provisional application No. 63/141,714, filed on Jan. 26, 2021.

(51) Int. Cl. H01L 21/02

(52) U.S. Cl. CPC H01L 21/02546; H01L 21/0243; H01L 21/02422

(57) ABSTRACT

Described herein are devices and methods for facet suppression in spalling of (100) GaAs by redirecting the fracture front along features created by buried nanoimprint lithography (NIL)-patterned SiO₂. Successful facet suppression using patterns that result in favorable fracture along the SiO₂/GaAs interface and/or through voids formed above the pattern in the coalesced layer is provided. These results allow for the design of patterns that would successfully interrupt the fracture front and suppress faceting that, combined with growth optimization, define a path forward for this technology to be used as a way to reduce the need for repreparation of the (100) GaAs substrate surface after spalling.

### CROSS-REFERENCE TO RELATED APPLICATIONS

This application claims priority from U.S. Provisional Patent Application No. 63/141,714, filed on Jan. 26, 2021, the contents of which are incorporated herein by reference in their entirety.

### CONTRACTUAL ORIGIN

This invention was made with government support under Contract No. DE-AC36-08G028308 awarded by the Department of Energy. The government has certain rights in the invention.

### SUMMARY

Described herein are devices and methods for facet suppression in spalling of (100) GaAs by redirecting the fracture front along features created by buried nanoimprint lithography (NIL)-patterned SiO₂. Successful facet suppression using patterns that result in favorable fracture along the SiO₂/GaAs interface and/or through voids formed above the pattern in the coalesced layer is provided. These results allow for the design of patterns that would successfully interrupt the fracture front and suppress faceting that, combined with growth optimization, define a path forward for this technology to be used as a way to reduce the need for repreparation of the (100) GaAs substrate surface after spalling.

Controlled spalling is an emerging technique developed for fast, scalable wafer reuse, but for the commonly used (100) GaAs substrate system, the process leaves large facets ranging from 5-10 um on the wafer surface. Removing them for wafer reuse requires a costly re-polishing step that limits the cost benefit of spalling as a wafer reuse technique. This facet suppression technique minimizes the surface roughness problems associated with spalling on GaAs. Methods of generating GaAs substrates are describe in M. Vaisman et al., “GaAs solar cells on nanopatterned Si substrates,” IEEE J. of Photovolt., vol. 8, no. 6, pp. 1635-1640, November 2018, which is hereby incorporated by reference in its entirety. Controlled spalling is described in Bedell, S. W., et al., “Layer transfer by controlled spalling,” J. Phys. D. Appl. Phys., vol. 46, no. 15, p. 152002, April 2013, which is also incorporated by reference in its entirety.

Substrate reuse techniques such as mechanical spalling or chemical etch-release layers have been investigated for many years, but none have as yet proven to be a clear winner from an economic standpoint, as costs for these techniques remain high. It can be seen by the foregoing that there remains a need in the art for eliminating the CMP step, and thus providing a more cost-effective route to enable substrate reuse.

In an aspect, provided is a device for manufacturing a semiconductor comprising a patterned nanoimprint lithography layer capable of reducing faceting during controlled spalling.

The semiconductor may comprise GaAs, for example, (100) GaAs. The patterned nanoimprint lithography layer may comprise SiO₂.

The patterned nanoimprint lithography layer may comprise elongated structures (i.e., structures having a length 2×, 5×, 10×, 25×, 100×, or optionally, 100× greater than their height and width). The elongated structures may be oriented parallel or substantially parallel to a [110] direction of a substrate of said semiconductor or the semiconductor substrate on which the nanoimprint lithography layer is deposited.

The elongated structures may have a width selected from the range of 100 nm to 1000 nm, 100 nm to 500 nm, 100 nm to 400 nm, 100 nm to 300 nm, 200 nm to 500 nm, 200 nm to 400 nm, or optionally, 200 nm to 300 nm.

The elongated structures may have a height selected from the range of 25 nm to 1000 nm, 50 nm to 500 nm, 100 nm to 500 nm, 50 nm to 250 nm, or optionally, 100 nm to 250 nm.

The elongated structures may have an offset selected from the range of 100 nm to 1000 nm, 100 nm to 500 nm, 100 nm to 300 nm, 200 nm to 1000 nm, 200 nm to 500 nm, or optionally, 200 nm to 300 nm.

The patterned nanoimprint lithography layer may be reusable.

In an aspect, provided is a method of manufacturing a semiconductor via controlled spalling utilizing any of the devices described herein.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1 provides an example configuration for controlled spalling with a buried NIL layer. The NIL layer guides the fracture and suppress faceting along the {110} GaAs planes to produce a more easily reusable surface after device removal.

FIG. 2 provides example patterns and effectiveness for facet interruption. Pattern A was produced at NREL and showed minimal facet suppression when the spalled perpendicular to the lines and some facet suppression when spalled parallel to the lines. Pattern B showed no facet suppression, evidenced by the large facets remaining on the substrate surface, due to minimal interaction of the pattern with the fracture front. Pattern C showed moderate facet suppression when spalled perpendicular to the line with fracture happening along the NIL/void layer for some length before faceting and successful facet suppression when spalled parallel to the lines, attributed to the continuous voids along the length of the spall above the NIL pattern.

FIGS. 3A-3B provide SEM images of pillars beneath HVPE growth. FIG. 3A is an overgrown, unspalled sample. FIG. 3B is a spalled sample. These images illustrate that the pillars remain upright after growth. The pillar in FIG. 3B aligns with the marks seen on the side of facets, indicating the spall did intersect the NIL layer but not interruption occurred.

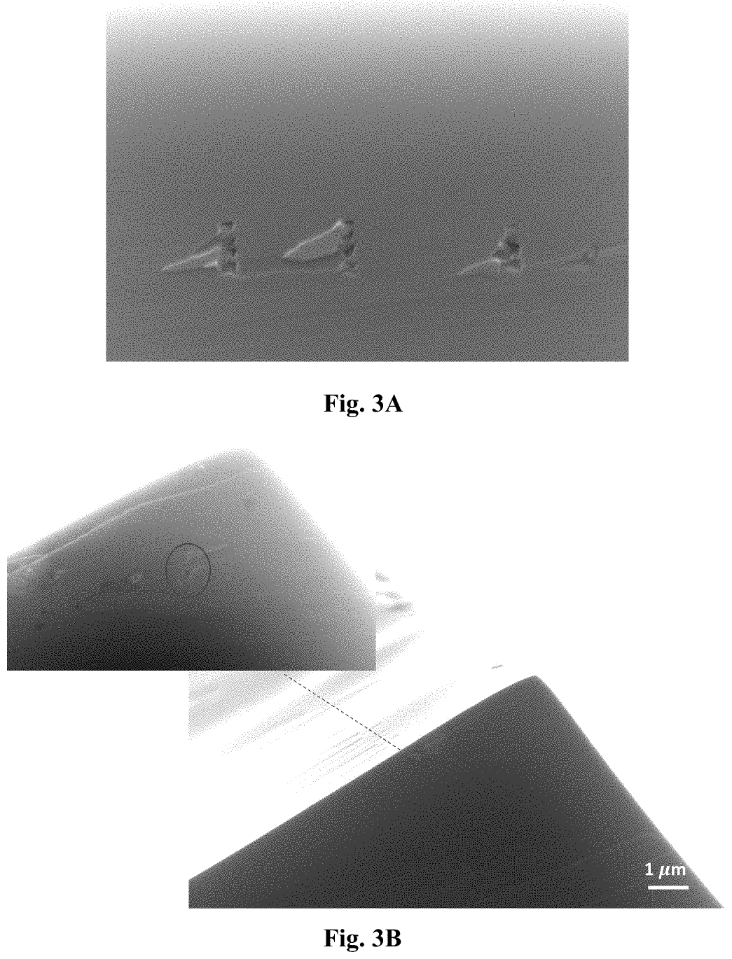

FIG. 4 provides a comparison of the various release layers described herein based on aspect ratio (height/width) and fill factor (%).

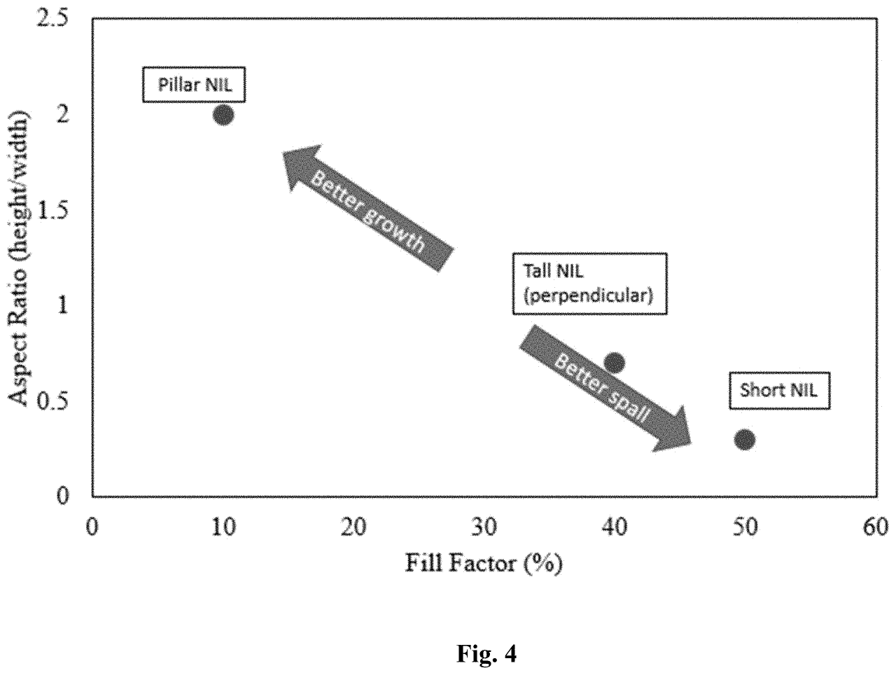

FIGS. 5A-5B are images of the pillar template point reference in FIG. 4 to illustrate growth quality. FIG. 5A is a Nomarksi image and FIG. 5B is ECCI. FIGS. 5A-5B show little evidence of threading dislocations and are smoother than other patterns tested.

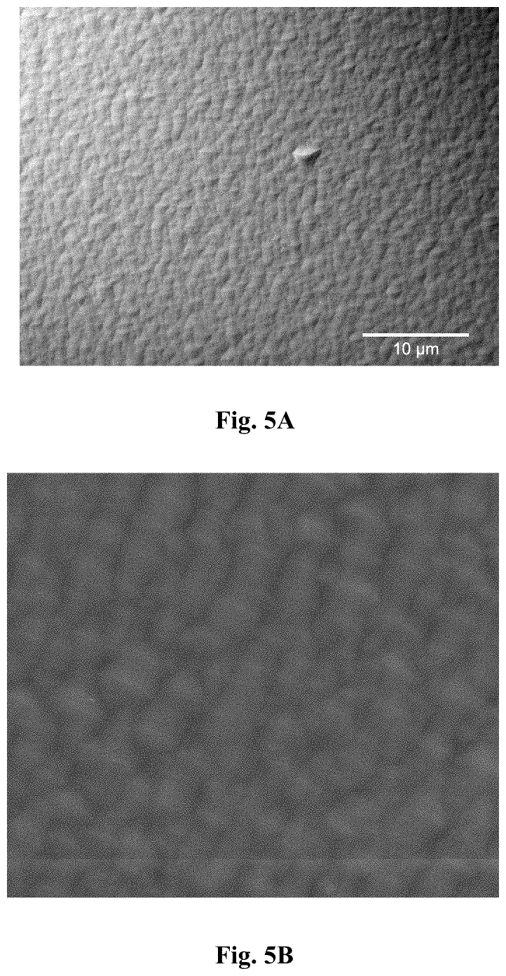

FIGS. 6A-6B are images of the tall template point reference in FIG. 4 to illustrate growth quality. FIG. 6A is a Nomarksi image and FIG. 6B is ECCI. FIGS. 6A-6B show high evidence of frequent threading dislocations and surface pits.

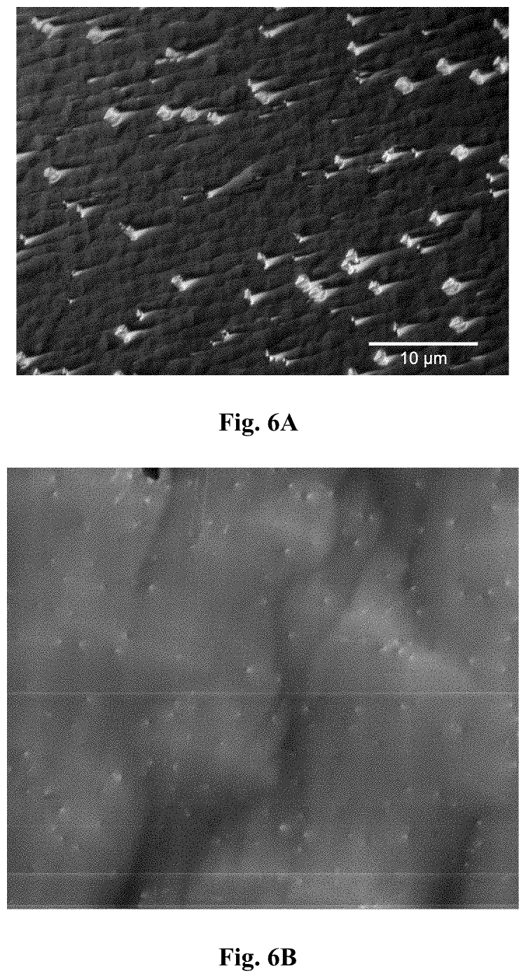

FIG. 7 is a Nomarksi image of the short template point reference in FIG. 4.

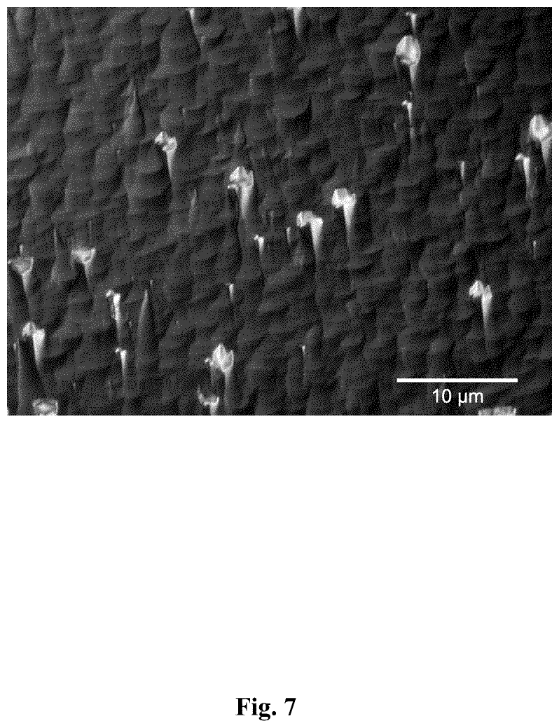

FIG. 8 is an image showing the void formation of the tall template, illustrating that the taller template has little or no void formation over the NIL.

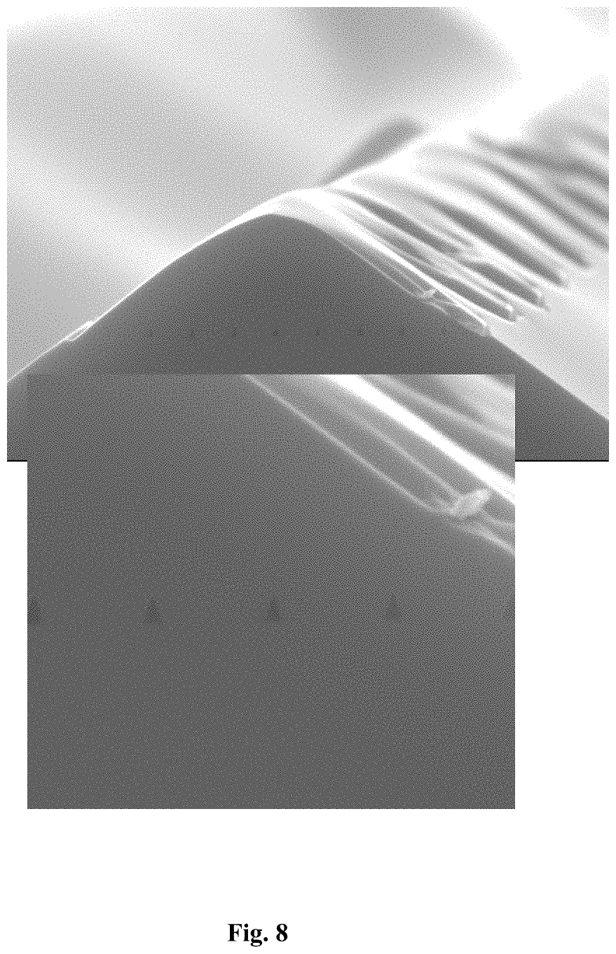

FIG. 9 is an image showing the void formation of the short template, here void space forms over the NIL line.

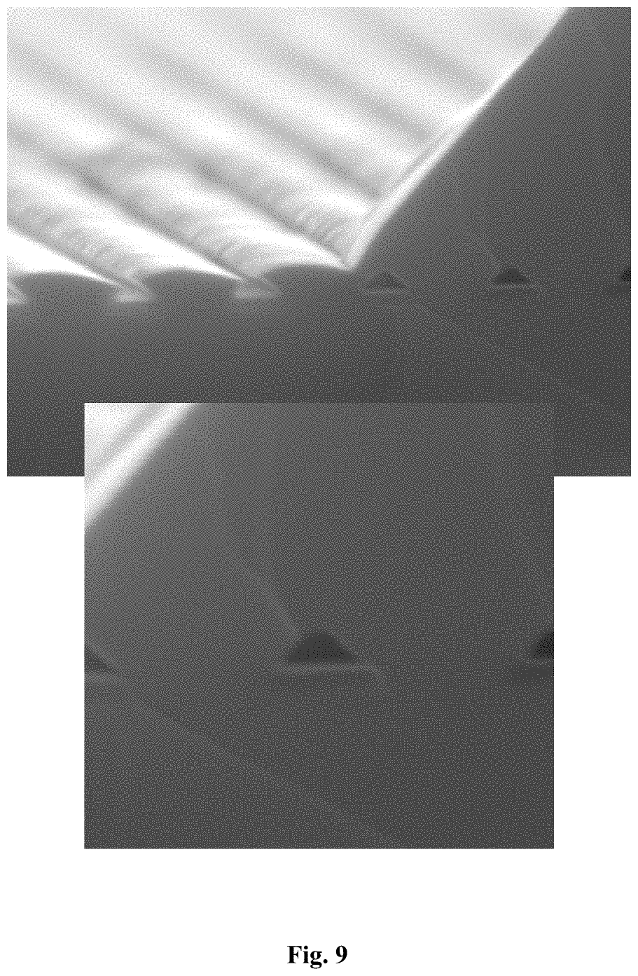

FIGS. 10A-10B compare the spall morphology between the pillar template and the tall template. FIG. 10A shows the pillar template and illustrates that fracture continues through the NIL layer without interruption and continue to occur. FIG. 10B shows the tall template and illustrates that fracture occurs along the NIL edge and large facets continue without interruption.

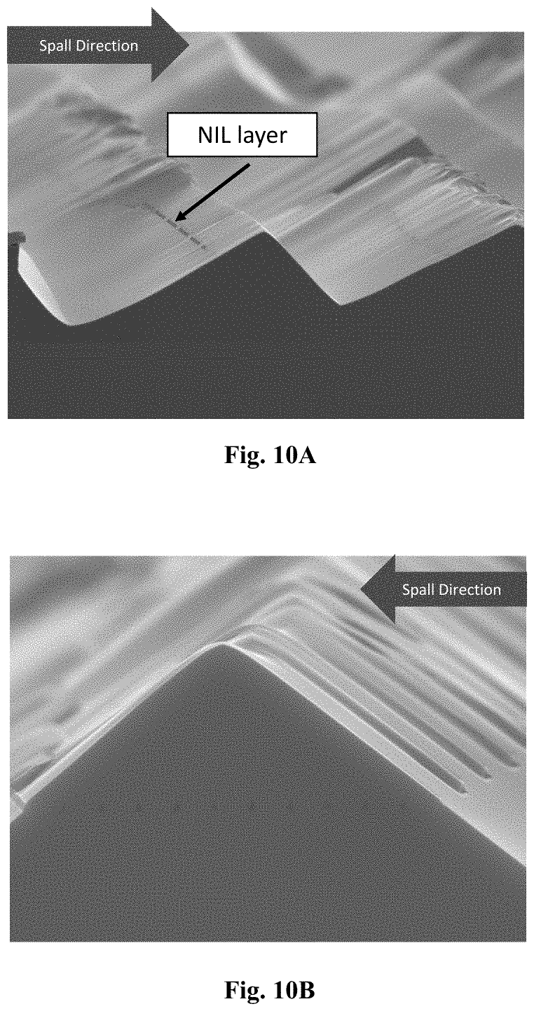

FIGS. 11A-11B show the spall morphology for the short template. Here the facture front is interrupted when it it's a void layer. In FIG. 11A faceting is suppressed to a small extent, where in FIG. 11B faceting is largely suppressed.

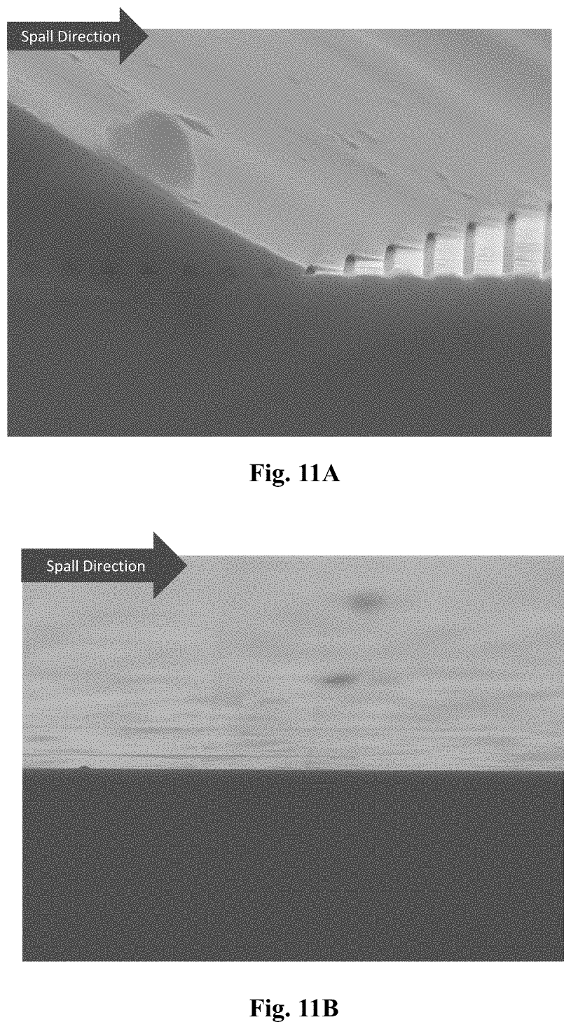

FIG. 12 shows the cross-section perpendicular to spall direction of the sample using the short pattern parallel to the NIL lines. Here the spall is generally flat between the lines and there is a small-scale arrest line type feature in the space between the arrest lines, but not obvious faceting.

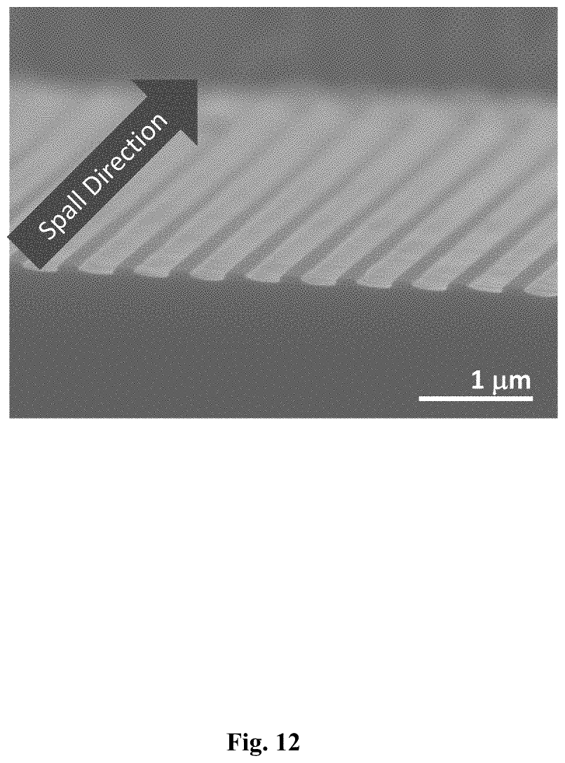

FIG. 13 are SEM images illustrating evidence of Walner lines between the NIL lines for the short pattern (FIG. 13A) and tall pattern (FIG. 13B).

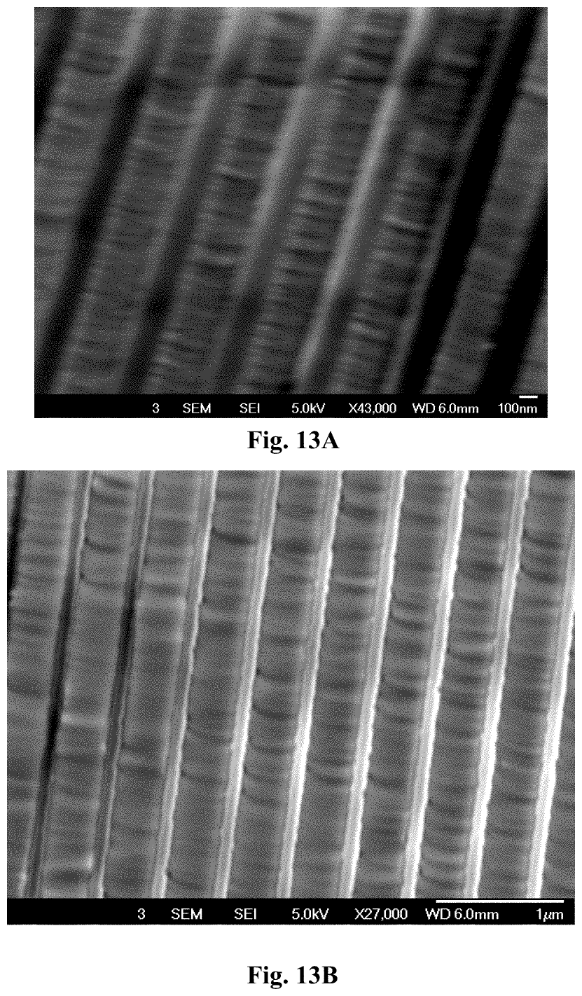

FIG. 14 shows stress versus current data for the NIL layer. Stress is calculated using the Stoney formula, from curvature of monolithic GaAs with representative Ni electroplating and measure Ni thickness.

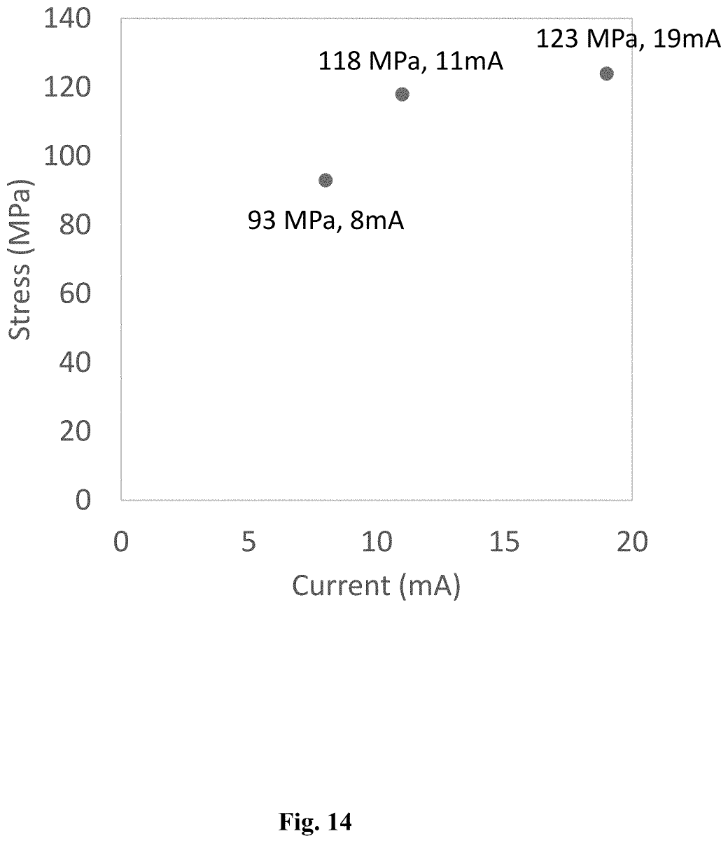

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The provided discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

### EXAMPLE 1—FACET SUPPRESSION IN (100) GAAS SPALLING VIA USE OF A NANOIMPRINT LITHOGRAPHY RELEASE LAYER

### Abstract

Controlled spalling is an emerging technique developed for fast, scalable wafer reuse, but for the commonly used (100) GaAs substrate system, the process leaves large facets ranging from 5-10 μm on the wafer surface. Removing them for wafer reuse requires a costly re-poshing step that limits the cost benefit of spalling as a wafer reuse technique. Described herein is the facet suppression in spalling of (100) GaAs by redirecting the fracture front along features created by buried nanoimprint lithography (NIL)-patterned SiO₂. Shown herein is successful facet suppression using patterns that result in favorable fracture along the SiO₂/GaAs interface and/or through voids formed above the pattern in the coalesced layer. Also presented are guidelines for design of patterns that successfully interrupt the fracture front and suppress faceting that, combined with growth optimization, define a path forward for this technology to be used as a way to reduce the need for repreparation of the (100) GaAs substrate surface after spalling.

### Introduction

III-V solar cells have the highest demonstrated efficiency of any photovoltaic technology, but their use has been limited to niche markets due to their high cost. The largest contributor to the cost of III-V solar cells is the cost of the single crystal substrate used in device growth. Controlled spalling recently emerged as a promising path toward reducing the substrate cost by removing the epitaxially grown device and allowing reuse of the substrate. The controlled spalling process utilizes a stressor layer to apply stress to the surface of a device. The applied stress helps initiate a lateral crack, parallel to the substrate surface, the depth of which is controlled by the stressor layer thickness, allowing the device to be mechanically exfoliated from the substrate and the substrate to be reused. The controlled spalling process is a potentially fast and easily scalable substrate reuse technique, making it desirable for photovoltaic device manufacturing. However, controlled spalling can leave a rough substrate surface as a result of the fracture, requiring repolishing of the wafer before reuse, which may limit the cost savings of this technique. Optimization of controlled spalling of (100)-oriented Ge improved the fracture surface so that good quality devices can be grown directly on the spalled surface without repolishing. However, in the case of (100)-oriented GaAs, the spalling process results in large triangular facets (5-10 μm peak-to-trough) across the substrate face due to fracture being most favorable along the nonpolar {110} planes that are 45° to the substrate surface. Removing the facets cannot be accomplished with process optimization of controlled spalling alone. Thus, described herein is an alternate path of introducing an interlayer into the structure to provide potentially more favorable avenues for fracture compared to fracture along the {110} planes, i.e., fracture along the interface of GaAs and the buried material and/or fracture through voids in the coalescence, with features placed sufficiently far apart to allow for epitaxial overgrowth and sufficiently close together to suppress faceting.

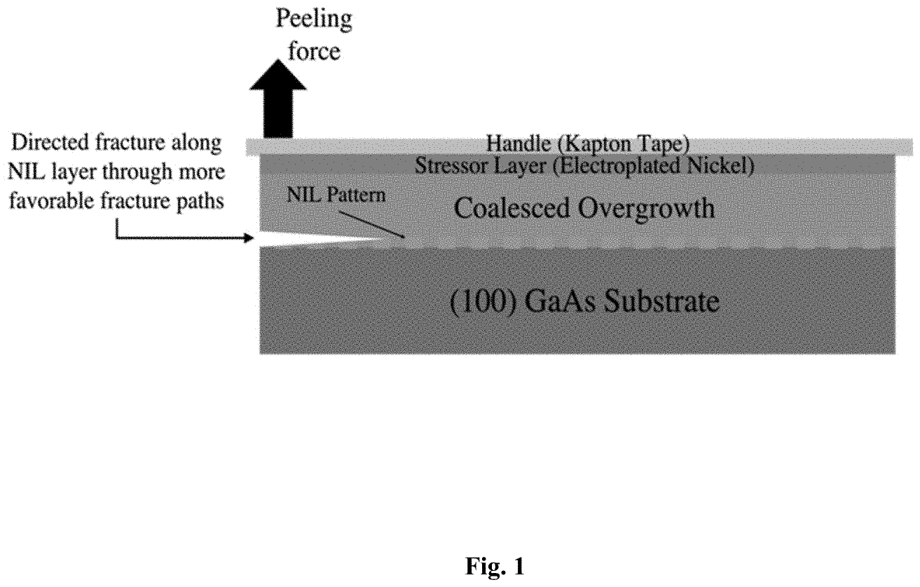

Silicon dioxide (SiO₂) patterned via Nanoimprint Lithography (NIL) has the potential to suppress faceting during the controlled spalling of (100) GaAs while still allowing high-quality material growth over the buried pattern for device growth. SiO₂ is a commonly used dielectric material that can easily be applied and patterned on a GaAs substrate. The fracture energy of SiO₂ is higher than that of GaAs along {110} planes (G_{I,SiO2}=5.41 Pa·m, G_{I,GaAs(110)}=2.27 Pa·m), so fracture through the SiO₂ feature is unlikely, but fracture along the SiO₂/GaAs interface having a fracture energy of G_{I,interface}=0.77 Pa·m is more favorable. Voids can also form as the growth front coalesces above the features during growth, providing another fracture path more favorable than fracture along {110} GaAs. NIL is a patterning technique that can be used to pattern a dielectric layer on III-V material with features much smaller than traditional photolithography, allowing for high quality coalescence due to the significantly reduced need for lateral overgrowth. FIG. 1 shows the technology concept of using a buried NIL structure to suppress faceting. In this work we present the use of buried NIL patterns as a means of interrupting the facet-forming fracture front during the controlled spalling process. The interaction of a spalling crack with three distinct NIL patterns is described, providing data to generate design criteria for facet disruption.

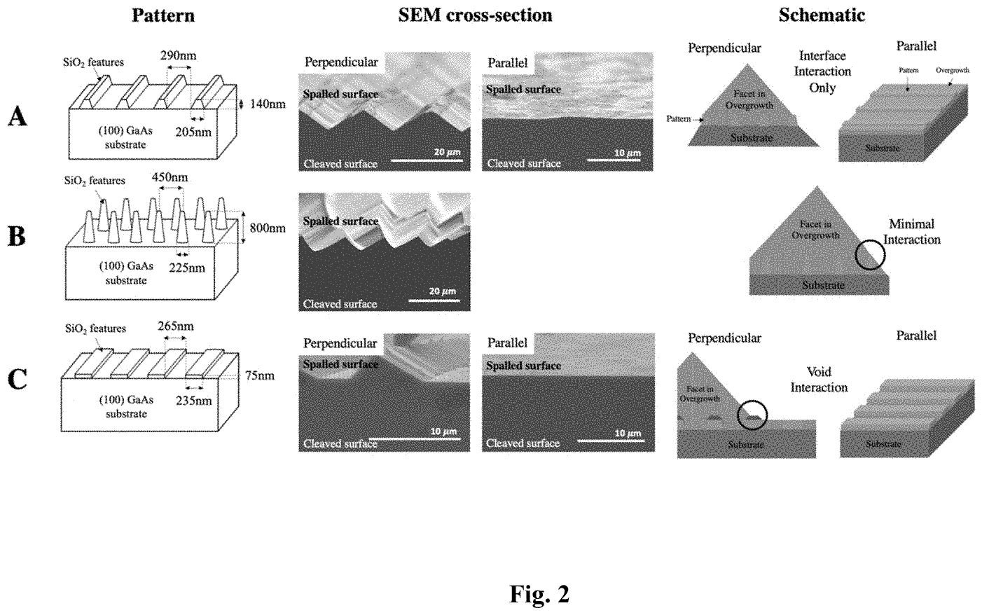

Sketches of the NIL patterns as described herein are shown in the left column of FIG. 2 along with nominal dimensions. Patterns A and C are made by patterning electron beam deposited SiO₂ on n-type (100) GaAs wafers following the procedure described in with patterned lines oriented parallel to the [110] direction. Both patterns used the same imprint template but differed in SiO₂ thickness. Pattern B, consisting of evenly spaced tapered pillars, was acquired from a commercial supplier. Epitaxial overgrowth of GaAs was performed at 650° C. using a custom-designed dual chamber hydride vapor-phase epitaxy (HVPE) reactor on 1 cm×1 cm pieces of the patterned substrates. Approximately 3 μm of n-type GaAs was grown over the NIL pattern before spalling.

After growth, the sample was etched in a 2:1:10 volumetric solution of NH₄OH:H₂O₂:H₂O for approximately 30 seconds to adjust the thickness of the overgrowth layer to ensure the spalling fracture occurred at the depth of the NIL pattern. A nickel stressor layer was deposited by galvanostatic electroplating at 30 mA/cm² for 14 minutes in a Watts nickel electrolyte. The sample was held in a custom 3D printed jig with front contacts to the coalesced growth surface. These electroplating conditions were optimized to propagate the fracture at approximately the depth of the buried NIL pattern. Controlled spalling was carried out using a linear-actuated roller to exert the peeling force and Kapton tape adhesive as the handle layer. Controlled spalling was performed both parallel and perpendicular to the patterned lines using NIL patterns A and C. For pattern B spalling was carried out in the <110> direction. The cross section and plan view of the spalled wafers were studied using SEM to determine the extent of facet suppression and the final state of the NIL pattern.

### Experimental Methods

The middle column of FIG. 2 shows the cross section SEM views of samples after controlled spalling, and the rightmost column illustrates the observed interactions of the facet front with the NIL pattern. The SEM image of pattern A in the perpendicular spalling situation shows the presence of large 5-10 μm high facets. The schematic illustrates the observation of the fracture front interacting with the SiO₂ feature, following the interface, then continuing along the favorable (110) plane as it does in monolithic material. There was no significant void formation in the coalesced material above the pattern, so fracture along the SiO₂/GaAs interface was the only favorable interaction for the fracture to experience. In the parallel spall, there was evidence of facet suppression, shown by the lack of facets in the parallel spall SEM image for pattern A. However, the rough spalled surface shown in the SEM image and rough perpendicular cross-section after cleavage of overgrown areas indicate poor growth quality, due to improper cleaning of the NIL template prior to growth. Therefore, it is inconclusive if the interaction of the facet front with the SiO₂/GaAs interface or the poor growth quality was the driving force for the apparent facet suppression in spalling of this sample in this orientation.

Large facets visible in the cross-sectional SEM image of pattern B (second row of FIG. 2) indicate the pattern did not facilitate facet suppression. Pattern B has the lowest SiO₂/GaAs interfacial area parallel to the surface of the patterns tested due to the low fill factor and tall and narrow shape of the pattern. There was no void formation above the pattern, making fracture along the SiO₂/GaAs interface the only fracture path more favorable than fracture along the {110} planes, but the shape and fill factor of the pattern limits the benefit that would be derived from fracturing along the SiO₂/GaAs interface. This pattern also exhibited an apparent toughening effect in some samples where the spalling fracture could not be initiated under the same conditions required for spalling of monolithic GaAs. This effect can be explained by considering that the pattern features may act as strong fibers oriented perpendicular to the intended fracture propagation direction and produce a fiber-toughened composite-like structure at the desired spall depth.

In the case of the perpendicular spall of pattern C (third row of FIG. 2), there was moderate facet suppression, visible in the cross-sectional SEM image for the perpendicular spall where large facets are abutted by flatter areas. Close inspection of the upper and lower fracture surfaces, and cross-sections of witness samples that were not spalled revealed there was significant void formation in the overgrowth above the pattern. Thus, the results in the SEM image show that both fracture through the voids and fracture along the SiO₂/GaAs interface were available paths for facet suppression in the fracture front during the spall. No evidence of similar void formation was observed in overgrowth of patterns A or B. The moderate facet suppression achieved in pattern C appears to primarily be the result of the interaction of the fracture front with the voids in the coalesced layer, shown in the schematic of the perpendicular spall with pattern C, combined with the higher fill factor of the pattern resulting in more interaction of the fracture front with the pattern/voids. Spalling perpendicular to this pattern results in discontinuity of interaction of the fracture front with the NIL pattern and voids, which gives the opportunity for the facture to deviate onto the {110} cleavage system and results in facets forming periodically and propagating until the fracture reengages with the NIL pattern. In the parallel spall, the facets were largely suppressed, shown in the cross-sectional SEM image in the third row of FIG. 2 where the NIL lines are aligned parallel to the plane of the page. The fracture also remained largely within the NIL/overgrowth, not penetrating deep into the substrate. In this configuration the voids in the overgrowth over the NIL features are continuous along the spall direction, providing a favorable fracture path along the NIL through the length of the spall. In the area where faceting was suppressed, the NIL pattern was largely preserved on the substrate and the fractured GaAs between the pattern lines did not show evidence of faceting, as depicted in the schematic for parallel spalling with pattern C. Faceting was not suppressed near the edges of the spall area due to known variations in the stressor layer thickness that result from the electroplating setup used in this study that move the desired spall depth away from the NIL/void layer. The results from the parallel spall indicate that with optimization of the spalling process, reuse of the NIL pattern multiple times without repatterning is possible.

### Conclusion

Described herein is successful facet suppression in (100) GaAs controlled spalling via the use of an NIL-patterned SiO₂ layer. The most successful facet interruption is achieved primarily from interaction with voids in the overgrowth formed above the pattern. The three patterns tested allow us to define guidelines for other designs for successful facet interruption. Combining high-quality overgrowth with a NIL pattern designed for optimal facet suppression is a promising improvement in wafer reuse options for (100) GaAs and lowering the cost of III-V solar cells.

The systems and methods described herein may be further understood by the following non-limiting examples:

Example 1. A device for manufacturing a semiconductor comprising:

a patterned nanoimprint lithography layer capable of reducing faceting during controlled spalling.

Example 2. The device of example 1, wherein said semiconductor comprises GaAs.

Example 3. The device of example 1 or 2, wherein said patterned nanoimprint lithography layer comprises SiO₂.

Example 4. The device of any of examples 1-3, wherein said patterned nanoimprint lithography layer comprises elongated structures.

Example 5. The device of any of examples 1-4, wherein said elongated structures are oriented parallel to a [110] direction of a substrate of said semiconductor.

Example 6. The device of example 5, wherein said elongated structures have a width selected from the range of 100 nm to 500 nm.

Example 7. The device of example 5, wherein said elongated structures have a width selected from the range of 200 nm to 300 nm.

Example 8. The device of any of examples 5-7, wherein said elongated structures have a height selected from the range of 25 nm to 1000 nm.

Example 9. The device of any of examples 5-7, wherein said elongated structures have a height selected from the range of 50 nm to 250 nm.

Example 10. The device of any of examples 5-9, wherein said elongated structures have an offset selected from the range of 100 nm to 500 nm.

Example 11. The device of any of examples 5-9, wherein said elongated structures have an offset selected from the range of 200 nm to 300 nm.

Example 12. The device of any of examples 5-11, wherein said elongated structures have a substantially rectangular cross section.

Example 13. The device of any of examples 1-12, wherein said patterned nanoimprint lithography layer is reusable.

Example 14. A method of manufacturing a semiconductor via controlled spalling utilizing any of the devices described in examples 1-13.

Example 15. A method comprising:

providing a patterned nanoimprint lithography layer;
growing a semiconductor layer on a surface of the patterned nanoimprint lithography layer;
removing the patterned nanoimprint layer, wherein the step of reducing does not generate spalling.

Example 16. The method of example 15, wherein said patterned nanoimprint lithography layer comprises elongated structures.

Example 17. The method of example 16, wherein said elongated structures are oriented parallel to a [110] direction of a substrate of said semiconductor.

Example 18. The method of example 16 or 17, wherein said elongated structures have a width selected from the range of 100 nm to 500 nm.

Example 19. The method of any of examples 16-18, said elongated structures have a substantially rectangular cross section.

Example 20. The method of any of examples 15-19, wherein said patterned nanoimprint lithography layer is reusable.

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. For example, when a device is set forth disclosing a range of materials, device components, and/or device configurations, the description is intended to include specific reference of each combination and/or variation corresponding to the disclosed range.

Every formulation or combination of components described or exemplified herein can be used to practice the invention, unless otherwise stated.

Whenever a range is given in the specification, for example, a density range, a number range, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter is claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

What is claimed is:

1. A device for manufacturing a semiconductor comprising:
a patterned nanoimprint lithography layer capable of reducing faceting during controlled spalling.

2. The device of claim 1, wherein said semiconductor comprises GaAs.

3. The device of claim 1, wherein said patterned nanoimprint lithography layer comprises SiO₂.

4. The device of claim 1, wherein said patterned nanoimprint lithography layer comprises elongated structures.

5. The device of claim 1, wherein said elongated structures are oriented parallel to a [110] direction of a substrate of said semiconductor.

6. The device of claim 5, wherein said elongated structures have a width selected from the range of 100 nm to 500 nm.

7. The device of claim 5, wherein said elongated structures have a width selected from the range of 200 nm to 300 nm.

8. The device of claim 5, wherein said elongated structures have a height selected from the range of 25 nm to 1000 nm.

9. The device of claim 5, wherein said elongated structures have a height selected from the range of 50 nm to 250 nm.

10. The device of claim 5, wherein said elongated structures have an offset selected from the range of 100 nm to 500 nm.

11. The device of claim 5, wherein said elongated structures have an offset selected from the range of 200 nm to 300 nm.

12. The device of claim 5, wherein said elongated structures have a substantially rectangular cross section.

13. The device of claim 1, wherein said patterned nanoimprint lithography layer is reusable.

14. A method comprising:
providing a patterned nanoimprint lithography layer;
growing a semiconductor layer on a surface of the patterned nanoimprint lithography layer;
removing the patterned nanoimprint layer, wherein the step of reducing does not generate spalling.

15. The method of claim 14, wherein said patterned nanoimprint lithography layer comprises elongated structures.

16. The method of claim 15, wherein said elongated structures are oriented parallel to a direction of a substrate of said semiconductor.

17. The method of claim 15, wherein said elongated structures have a width selected from the range of 100 nm to 500 nm.

18. The method of claim 15, said elongated structures have a substantially rectangular cross section.

19. The method of claim 14, wherein said patterned nanoimprint lithography layer is reusable.
